(19) United States
(12) Patent Application Publication
(10) Pub. No.: US 2023/0100375 A1
(43) Pub. Date: Mar. 30, 2023

(54) REPAIR AND PERFORMANCE CHIPLET

(71) Applicant: Intel Corporation, Santa Clara, CA (US)

(72) Inventors: Gerald PASDAST, San Jose, CA (US); Sathya Narasimman TIAGARAJ, San Jose, CA (US); Adel A. ELSHERBINI, Tempe, AZ (US)

(21) Appl. No.: 17/485,198

(22) Filed: Sep. 24, 2021

(51) Int. Cl. H01L 25/065; H01L 23/00

(52) U.S. Cl. CPC H01L 25/0657; H01L 25/0655; H01L 24/08; H01L 24/16; H01L 2225/06517; H01L 2225/0652; H01L 2225/06541; H01L 2225/06562; H01L 2924/1431; H01L 2924/1432; H01L 2924/14335; H01L 2225/06596; H01L 2224/16146; H01L 2224/16225; H01L 2224/08146; H01L 23/49833

(57) ABSTRACT

Embodiments disclosed herein include die modules and electronic packages. In an embodiment, a die module comprises a base die where the base die comprises a functional block. In an embodiment, the die module further comprises a chiplet coupled to the base die proximate to the functional block. In an embodiment, the chiplet comprises similar functionality as the functional block.

### TECHNICAL FIELD

Embodiments of the present disclosure relate to electronic packages, and more particularly to electronic packages with repair chiplets or performance enhancement chiplets.

### BACKGROUND

On existing monolithic and coarse-grain disaggregated system on chips (SOCs), performance is limited by process variation gradients across the die. For example, the slowest processor core amongst an array of cores will determine the speed grade of the SOC. Existing processors also include spare cores within the core array for yield recovery purposes. At the time of testing, defective components are identified and replaced with the spares. For example, a defective processing unit would be disabled and an existing spare enabled in its place. The need for additional spare cores increases the footprint of the SOC which translates to higher silicon cost. Latency increases are also generated due to longer distances that need to be traveled due to the bigger die. Additionally, for some functional blocks replacement is not as simple. For example, in the case of an IO lane, replacement typically requires a different package design variant in order to accommodate the replacement lane.

Some performance limitations may also be accommodated by using an increased voltage. Increasing the voltage to a functional block can compensate for a slow process gradient. However, increasing the voltage comes at the cost of increased power consumption, and is not desirable. Ultimately, when a slow functional block is generated, it may result in the SOC being down-binned to a less profitable device.

### BRIEF DESCRIPTION OF THE DRAWINGS

FIG. 1A is a cross-sectional illustration of an electronic package with a die module that includes a replacement chiplet over a base die, in accordance with an embodiment.

FIG. 1B is a cross-sectional illustration of a hybrid bonding interface between the replacement chiplet and the base die, in accordance with an embodiment.

FIG. 2 is a cross-sectional illustration of an electronic package with a die module that includes a replacement chiplet and dummy dies over a base die, in accordance with an embodiment.

FIG. 3 is a cross-sectional illustration of an electronic package with a die module that includes a replacement chiplet between a base die and a package substrate, in accordance with an embodiment.

FIG. 4 is a cross-sectional illustration of an electronic package with a die module that includes a replacement chiplet and dummy dies between a base die and a package substrate, in accordance with an embodiment.

FIG. 5 is a cross-sectional illustration of an electronic package with a die module that includes a first replacement chiplet on a base die and a second replacement chiplet below the base die, in accordance with an embodiment.

FIG. 6 is a schematic of the switching circuitry that can be used to switch between a defective functional block and a replacement chiplet, in accordance with an embodiment.

FIG. 7 is a cross-sectional illustration of a die module that comprises replacement chiplets for different functional blocks on the base die, in accordance with an embodiment.

FIG. 8 is a cross-sectional illustration of an electronic system with a die module that includes a base die and replacement chiplets, in accordance with an embodiment.

FIG. 9 is a schematic of a computing device built in accordance with an embodiment.

### EMBODIMENTS OF THE PRESENT DISCLOSURE

Described herein are electronic packages with repair chiplets or performance enhancement chiplets, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, systems on chips (SOCs) are often limited in performance by slow or otherwise damaged functional blocks within the SOC. In some instances, poorly performing functional blocks can be replaced by spare functional blocks that are formed on the SOC. However, the inclusion of spare functional blocks takes up valuable silicon real estate and increases the cost and form factor of the SOC. In other embodiments, slow functional blocks can be mitigated by increasing the voltage to that functional block. However, this increases power consumption and is not desirable.

Accordingly, embodiments disclosed herein include die modules that have replacement chiplets. The replacement chiplets have the functionality of the damaged or otherwise non-optimal functional blocks on a base die. Circuitry on the base die turns off the functional block and allows for the replacement chiplet to function in the place of the damaged functional block. The replacement chiplets can be used to replace one or more of cache, core, IO lanes, and/or an entire PHY layer. In the specific case of IO lanes, the replacement chiplet can re-route to the same bump with a replacement repair lane. This eliminates the need for alternative package architectures as is currently the case with existing devices.

The ability to make the replacement is dependent on the inclusion of small form factor interconnects between the replacement chiplet and the base die. For example, interconnects with a pitch of approximately 10 μm or smaller may be used in some embodiments. In yet another embodiment, the pitch may be approximately 1 μm or smaller. As used herein, “approximately” may refer to a range that is plus or minus 10% from the stated value. For example, approximately 10 μm may refer to a range between 9 μm and 11 μm.

Such small pitches are not feasible using typical first level interconnect (FLI) architectures. Instead, embodiments disclosed herein include the use of hybrid bonding interconnects in order to provide the ultra-small pitches necessary to enable architectures disclosed herein. Hybrid bonding architectures generally include interfaces with two separate bonding surfaces. A first surface is a dielectric and a second surface is a conductive interconnect. At low temperatures, the first surfaces (i.e., dielectric-to-dielectric) begin to bond together. At higher temperatures, the second surfaces (i.e., conductive-to-conductive) begin to bond by an interdiffusion process. In some embodiments, the interdiffusion process makes it so there is no discernable boundary between the opposing interconnects.

Accordingly, embodiments disclosed herein avoid the need to make the base die bigger while still allowing for redundancy. The redundancy is provided by the replacement chiplets instead of being fabricated on the base die. Additionally, embodiments account for IO lane defects (e.g., device defects, broken transistors, metal shorts to power or ground, etc.) by effectively disabling defective IO lanes (or entire PHYs) and muxing-in replacement IO lanes (or entire PHYs).

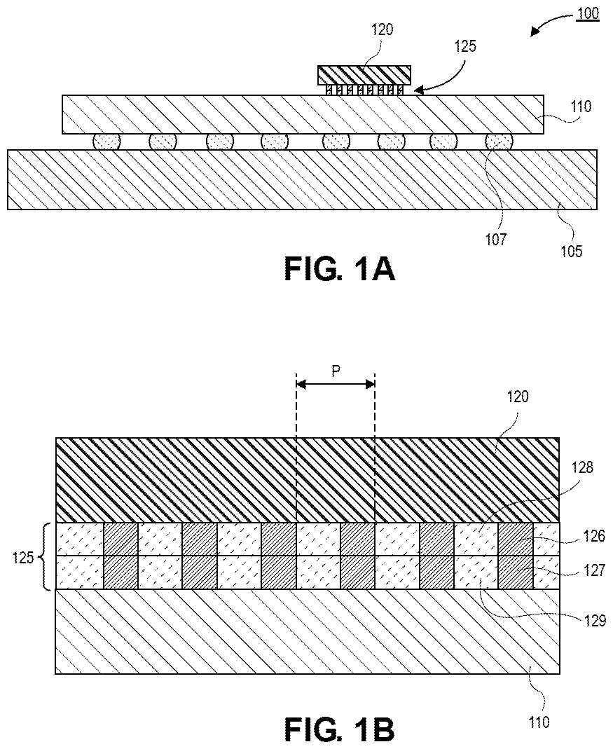

Referring now to FIG. 1A, a cross-sectional illustration of an electronic package 100 is shown, in accordance with an embodiment. In an embodiment, the electronic package 100 may comprise a package substrate 105. The package substrate 105 may be a traditional electronic package substrate, such as an organic substrate. The package substrate 105 may include a core or the package substrate 105 may be coreless. In some embodiments, the package substrate 105 may also be an interposer type substrate, such as a glass interposer, a silicon interposer, or the like.

In an embodiment, the package substrate 105 may be coupled to a base die 110. For example, interconnects 107, such as first level interconnects (FLIs) may be used to couple the package substrate 105 to the base die 110. For example, the interconnects 107 may be solder interconnects, copper bumps, or any other suitable architecture.

In an embodiment, the base die 110 may be a die with a plurality of functional blocks. For example, the functional blocks may include processor cores, memory (e.g., DDR or any other memory type), IO lanes, or the like. The base die 110 may be considered an SOC in some embodiments. In a particular embodiment, one or more redundant functional blocks are omitted from the base die 110. That is, if there is a damaged or otherwise non-functional functional block in the base die 110, the repair may be made using a replacement chiplet, as will be described in greater detail below. This allows for the footprint of the base die 110 to be reduced, thereby reducing costs and improving latency.

In an embodiment, one or more replacement chiplets 120 may be coupled to the base die 110. For example, interconnects 125 may be provided between the replacement chiplet 120 and the base die 110. The interconnects 125 may be a small pitch interconnect architecture. In an embodiment, the interconnects 125 have a pitch that is smaller than the pitch of the interconnects 107. For example, the interconnects 125 may be hybrid bonding interconnects. Details on the hybrid bonding are provided in greater detail below with respect to FIG. 1B.

In an embodiment, the replacement chiplet 120 comprises the functionality of one of the functional blocks of the base die 110. For example, the replacement chiplet 120 may be a processor core, a memory block, or an IO lane. Since only a single functionality is necessary, the footprint of the replacement chiplet 120 may be matched to the footprint of the respective functional block. The replacement chiplet 120 may be directly over the functional block within the base die 110 that is being replaced. Through silicon vias (not shown) may be provided through the base die 110 in order to provide connections to the overlying replacement chiplet 120. Additionally, while shown as having a substantially flat backside surface, it is to be appreciated that the interconnect pads may be provided across the entire backside surface in order to accommodate the placement of replacement chiplets 120 at any location across the base die 110.

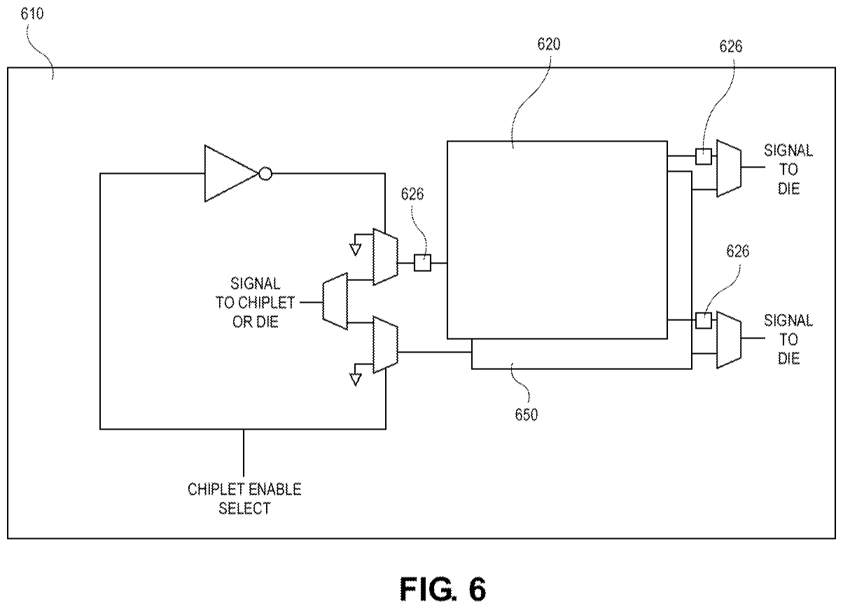

In an embodiment, the base die 110 may also comprise circuitry for selecting the replacement chiplet 120 over the defective functional block. That is, the circuitry turns off the defective functional block and replaces the active circuitry with the replacement chiplet. Since each functional block is capable of being replaced, it is to be appreciated that the switching circuitry between the functional block and the replacement chiplet is found on every functional block, even though a replacement chiplet 120 is formed over only damaged functional blocks. A more detailed description of the selector circuitry is provided below with respect to FIG. 6.

Referring now to FIG. 1B, a cross-sectional illustration of the interconnects 125 between the replacement chiplet 120 and the base die 110 is shown, in accordance with an embodiment. In an embodiment, the interconnects 125 are a hybrid bonding interconnect architecture. That is, the interface between the replacement chiplet 120 and the base die 110 includes at least two different material interfaces. In an embodiment, a first interface is a low temperature interface, and the second interface is a higher temperature interface.

In an embodiment, the base die 110 comprises a first dielectric 129 and first bumps 127. The first dielectric 129 may comprise silicon and oxygen (e.g., SiO_{X}), and the first bumps 127 may comprise a conductive material (e.g., copper). In an embodiment, the replacement chiplet 120 may comprise a second dielectric 128 and second bumps 126. The second dielectric 128 may comprise silicon and oxygen (e.g., SiO_{X}), and the second bumps 126 may comprise a conductive material (e.g., copper). The dielectric layers (i.e., the first dielectric 129 and the second dielectric 128) may surround the respective bumps (i.e., the first bumps 127 and the second bumps 126).

Surface planarity is an important consideration when implementing hybrid bonding. In a particular embodiment, a top surface of the first dielectric 129 may be substantially coplanar with a top surface of the first bumps 127. As used herein substantially coplanar may refer to surfaces that are within approximately 1 μm from being perfectly coplanar. In some embodiments, the first bumps 127 may be recessed partially below the top surface of the first dielectric 129. For example, the top surfaces of the first bumps 127 may be approximately 10 nm to 100 nm below a top surface of the first dielectric 129. Similarly, the second bumps 126 and the second dielectric 128 may have substantially coplanar surfaces, or the second bumps 126 may be slightly recessed from the second dielectric 128 (e.g., by between approximately 10 nm and 100 nm).

In an embodiment, the hybrid bonding process results in the bonding of the first dielectric 129 to the second dielectric 128 and the bonding of the first bumps 127 to the second bumps 126. At low temperatures, the first surfaces (i.e., first dielectric 129 to second dielectric 128) begin to bond together. At higher temperatures, the second surfaces (i.e., the first bumps 127 to the second bumps 126) begin to bond by an interdiffusion process. In some embodiments, the interdiffusion process makes it so there is no discernable boundary between the first bumps 127 and the second bumps 126. That is, it may appear to be a single interconnect between the base die 110 and the replacement chiplet 120.

The use of hybrid bonding allows for the bumps 127, 126 to have a small pitch P. In an embodiment, the pitch P is smaller than the pitch of the interconnects 107 between the base die 110 and the package substrate 105. In some embodiments, the pitch P may be approximately 10 μm or smaller or approximately 1 μm or smaller. The small pitch P allows for high density interconnects that enable the replacement of the functional block with the replacement chiplet 120.

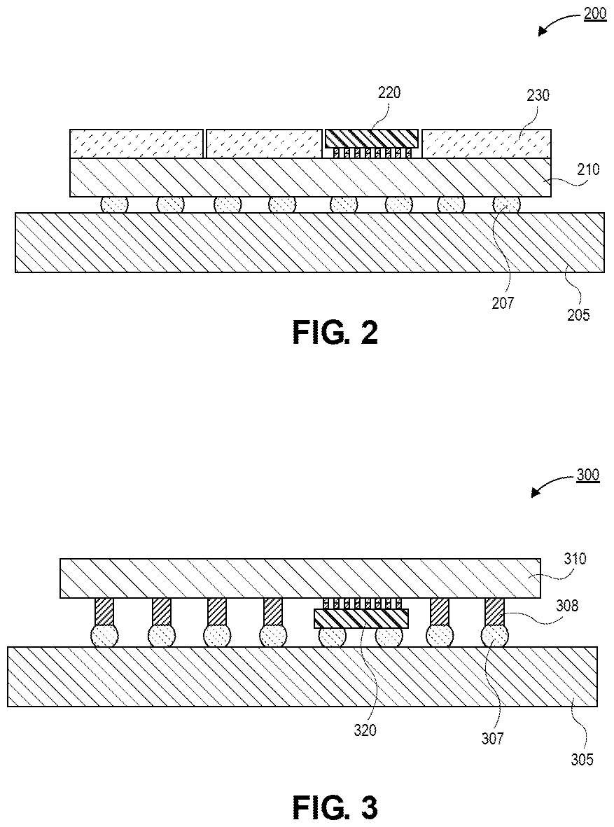

Referring now to FIG. 2, a cross-sectional illustration of an electronic package 200 is shown, in accordance with an embodiment. In an embodiment, the electronic package 200 comprises a package substrate 205 and a die module. The package substrate 205 may be an organic substrate in some embodiments. The package substrate 205 may also be substantially similar to the package substrate 105 described in greater detail above.

In an embodiment, the die module may include a base die 210. The base die 210 may be electrically coupled to the package substrate 205 by interconnects 207. The interconnects 207 may be any suitable FLI architecture, such as those described in greater detail above. In an embodiment, the base die 210 may comprise a plurality of functional blocks (not shown). For example, the base die 210 may comprise processor cores, memory blocks, IO lanes, and the like. In an embodiment, the base die 210 may be an SOC.

In an embodiment, the die module may further comprise a replacement chiplet 220. The replacement chiplet 220 may include functionality to replace one of the functional blocks on the base die 210. For example, when one of the functional blocks of the base die is defective and/or otherwise damaged, the replacement chiplet 220 may be attached to the base die 210 over the defective functional block. Circuitry within the base die 210 then selects the use of the replacement chiplet 220 over the use of the damaged functional block. A more detailed description of the selector circuitry is provided below with respect to FIG. 6.

In an embodiment, the replacement chiplet 220 is coupled to the base die 210 with a high density interconnect architecture. For example, a hybrid bonding architecture may be used in some embodiments. The hybrid bonding interface may be similar to the interface illustrated above with respect to FIG. 1B. That is, a dielectric layer bond and a conductive layer bond may be provided between the replacement chiplet 220 and the base die 210. In an embodiment, the pitch of the interconnects at the interface may be approximately 10 μm or less, or approximately 1 μm or less.

In an embodiment, the die module further comprises one or more dummy dies 230. The dummy dies 230 may be silicon dies without active circuitry. That is, the dummy dies 230 may not be electrically coupled to the active circuitry of the base die 210. The dummy dies 230 are provided for mechanical and thermal control reasons. For example, the dummy dies 230 may have a backside surface that is substantially coplanar with a backside surface of the replacement chiplet 220. As such, a heat spreader and/or an integrated heat spreader (IHS) can be simply provided across the entire backside surface of the die module.

In an embodiment, the dummy dies 230 may be attached to the base die 210 using any suitable attachment architecture. In some embodiments, the dummy dies 230 are attached to the base die 210 using a hybrid bonding interface (e.g., similar to the bonding of the replacement chiplet 220 to the base die 210). In other embodiments, the dummy dies 230 may be attached to the base die 210 using an adhesive material such as a die attach film (DAF) or the like. In an embodiment, the interconnect architecture minimizes the thermal resistance between the base die 210 and the dummy die 230 in order to provide improved thermal control.

Referring now to FIG. 3, a cross-sectional illustration of an electronic package 300 is shown, in accordance with an embodiment. In an embodiment, the electronic package 300 comprises a package substrate 305 and a die module attached to the package substrate 305. The package substrate 305 may be substantially similar to the package substrate 105 described in greater detail above. In an embodiment, the die module comprises a base die 310 and a replacement chiplet 320. The base die 310 may comprise a plurality of functional blocks, such as a processor core, a memory block, or an IO lane.

In an embodiment, the replacement chiplet 320 may be provided between the base die 310 and the package substrate 305. That is, the replacement chiplet 320 may be below the base die 310 in some embodiments. The replacement chiplet 320 may be disposed over a defective or otherwise damaged functional block within the base die 310. Circuitry within the base die 310 may then be used to select the replacement chiplet 320 and functionally turn off the defective or damaged functional block within the base die 310. A more detailed description of the selector circuitry is provide below with respect to FIG. 6.

In an embodiment, the replacement chiplet 320 is coupled to the base die 310 with a high density interconnect architecture. For example, a hybrid bonding architecture may be used in some embodiments. The hybrid bonding interface may be similar to the interface illustrated above with respect to FIG. 1B. That is, a dielectric layer bond and a conductive layer bond may be provided between the replacement chiplet 320 and the base die 310. In an embodiment, the pitch of the interconnects at the interface may be approximately 10 μm or less, or approximately 1 μm or less.

In an embodiment, the replacement chiplet 320 may comprise TSVs (not shown) through a thickness of the replacement chiplet 320. The TSVs allow for electrical coupling through a thickness of the replacement chiplet 320 in order to connect to underlying interconnects 307 that connect to the package substrate 305. Additionally, since the replacement chiplet 320 is between the base die 310 and the package substrate 305, pillars 308 may also be needed in order to increase the standoff height between the base die 310 and the package substrate 305. The pillars 308 may extend out from the base die 310 in some embodiments. In other embodiments, the orientation of the pillars 308 and the interconnects 307 may be switched so that the pillars 308 extend up from the package substrate 305.

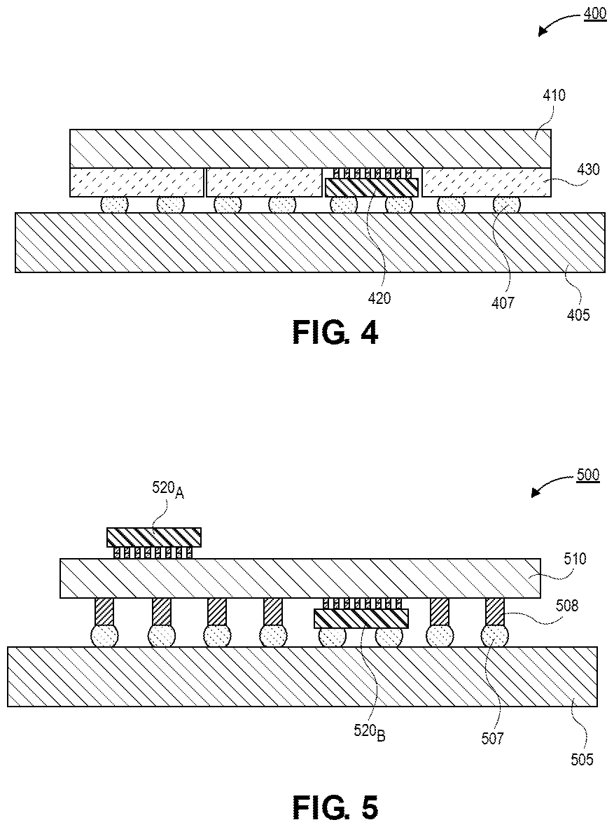

Referring now to FIG. 4, a cross-sectional illustration of an electronic package 400 is shown, in accordance with an embodiment. In an embodiment, the electronic package 400 comprises a die module that is coupled to a package substrate 405. The package substrate 405 may be substantially similar to the package substrate 105 described in greater detail above. In an embodiment, the die module is coupled to the package substrate 405 by interconnects 407, such as any suitable FLI architecture.

In an embodiment, the die module comprises a base die 410. The base die 410 may comprise a plurality of functional blocks (not shown). For example, the functional blocks may comprise processor cores, memory blocks, IO lanes, and the like. In an embodiment, the base die 410 is an SOC. In an embodiment, the die module further comprises a replacement chiplet 420. The replacement chiplet 420 may be coupled to the base die 410. For example, the replacement chiplet 420 is provided between the base die 410 and the package substrate 405. The replacement chiplet 420 may be provided over a defective functional block of the base die 410. Similar to embodiments described above, circuitry on the base die 410 may be used to select the replacement chiplet 420 and functionally turn off the defective or damaged functional block within the base die 410.

In an embodiment, the die module may further comprise one or more dummy dies 430. The dummy dies 430 may be substantially similar to the dummy dies 230 described in greater detail above. That is, the dummy dies 430 may be a silicon substrate without any active circuitry. However, it is to be appreciated that the dummy dies 430 may have TSVs (not shown) in order to couple between the base die 410 and the package substrate 405. Providing dummy dies 430 may simplify manufacturing and provide more mechanical support than if only the replacement chiplet 420 was between the base die 410 and the package substrate 405. In an embodiment the dummy dies 430 may be adhered to the base die 410 with any suitable interconnect architecture. In some embodiments, the dummy dies 430 may be coupled to the base die 410 with hybrid bonding processes.

Referring now to FIG. 5, a cross-sectional illustration of an electronic package 500 is shown, in accordance with an additional embodiment. In the illustrated embodiment, a die module is coupled to a package substrate 505. The package substrate 505 may be substantially similar to the package substrate 105 described in greater detail above.

In an embodiment, the die module may comprise a base die 510. The base die 510 may comprise functional blocks, such as processor cores, memory blocks, and IO lanes. In a particular embodiment, the base die 510 is an SOC. The base die 510 may have one or more defective or otherwise damaged functional blocks. As such, replacement chiplets 520 may be included in the die module. The replacement chiplets 520_{A} and 520_{B} may be provided over opposite sides of the base die 510. For example, replacement chiplet 520_{A} may be above the base die 510, and replacement chiplet 520_{B} may be between the base die 510 and the package substrate 505. Though, it is to be appreciated that the replacement chiplets 520_{A} and 520_{B} may be positioned on the same side of the base die 510 in some embodiments. The replacement chiplets 520_{A} and 520_{B} may replace the functionality of a damaged underlying (or overlying) functional block of the base die 510. In order to access the replacement chiplets 520, the base die 510 may have selector circuitry. The circuitry will be described in greater detail in conjunction with FIG. 6.

In an embodiment, the replacement chiplets 520 may be coupled to the base die 510 with high density interconnects. For example, the replacement chiplets 520 may be bonded to the base die 510 with a hybrid bonding process. The hybrid bonding interface may be similar to the interface shown in FIG. 1B.

In an embodiment, the base die 510 may be coupled to the package substrate 505 by pillars 508 and interconnects 507. The pillars 508 provide an increased standoff height to accommodate the underlying replacement chiplet 520_{B}. Additionally, the underlying replacement chiplet 520_{B} may have TSVs (not shown) in order to provide a connection from the base die 510 down to the package substrate 505.

Referring now to FIG. 6, a schematic illustration of the muxing circuitry that allows for switching between the functional block 650 on the base die 610 and the replacement chiplet 620 that is attached to the base die 610 is shown, in accordance with an embodiment. As shown, transistors for selecting which block to use (i.e., the functional block 650 or the replacement chiplet 620) are provided (schematically to the left of the blocks 650 and 620). When the replacement chiplet 620 is present, it is coupled to the circuitry by interconnects 626. The interconnects 626 may be the conductive interconnects of the hybrid bonding interface described in greater detail above. As such, the circuitry can be switched to process data on the replacement chiplet 620. Processed data may then return to the base die 610 by interconnects 626 and muxing transistors (schematically on the right of the blocks 620 and 650). When the replacement chiplet 620 is not present, the circuitry may have an open, and the switching circuitry selects the completed path through the functional block 650. It is also to be appreciated that in a no-repair case, a dummy IO lane, a PHY, or a core may be placed on top of the functional block 650. In such an instance dangling bumps (i.e., interconnects 626 for the mux outputs or the mux repair inputs) may be avoided.

That is, it is to be appreciated that the muxing circuitry may be present for each functional block 650, even when there are no replacement chiplets 620. This is because there is no way of knowing which of the functional blocks 650 may be damaged or otherwise defective until testing. Upon testing, the damaged or defective functional blocks 650 are patched over using replacement chiplets 620 and the existing muxing circuitry of the base die 610.

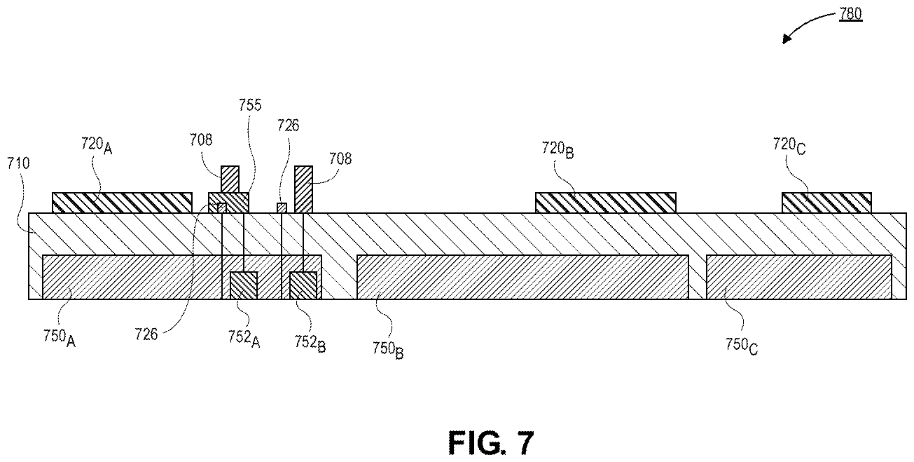

Referring now to FIG. 7, a cross-sectional illustration of a die module 780 is shown, in accordance with an embodiment. As shown, the die module 780 comprises a base die 710. A plurality of functional blocks 750 are provided in the base die 710. For example, the functional blocks 750 may comprise processor cores, memory blocks, and IO lanes. In the illustrated embodiment, there are three functional blocks 750_{A}-750_{C}, though it is to be appreciated that any number of functional blocks 750 may be included in the die 710.

In an embodiment, replacement chiplets 720 may be provided over the functional blocks 750. The replacement chiplets 720 may be configured to replace functionality of the underlying functional blocks 750. The replacement chiplets 720_{A}-720_{C} may be coupled to the base die 710 using hybrid bonding interconnects, as described in greater detail above.

In some embodiments, a replacement chiplet may replace a smaller portion of the functionality than an entire functional block 750. For example, functional block 750_{A} may be an IO block. IO lanes 752_{A} and 752_{B} may be provided within the functional block 750_{A}. As shown, IO lane 752_{B} is a functional IO lane, and IO lane 752_{A} is defective. In order to correct the IO lane 752_{A}, a replacement chiplet 755 is coupled to the base die 710 by interconnect 726 (e.g., a hybrid bonding interconnect). External connection 708 may then be provided over the replacement chiplet 755. As such, the replacement chiplet 755 is routed to the same interconnect that would have been used had the IO lane 752_{A} been functional. This allows for the same package substrate (not shown) to be used for the die module 780. Additionally, it is to be appreciated that the functional IO lane 752_{B} includes a hybrid interconnect 726. However, since no replacement chiplet is needed for the functional IO lane 752_{B}, the hybrid interconnect 726 is not connected to anything.

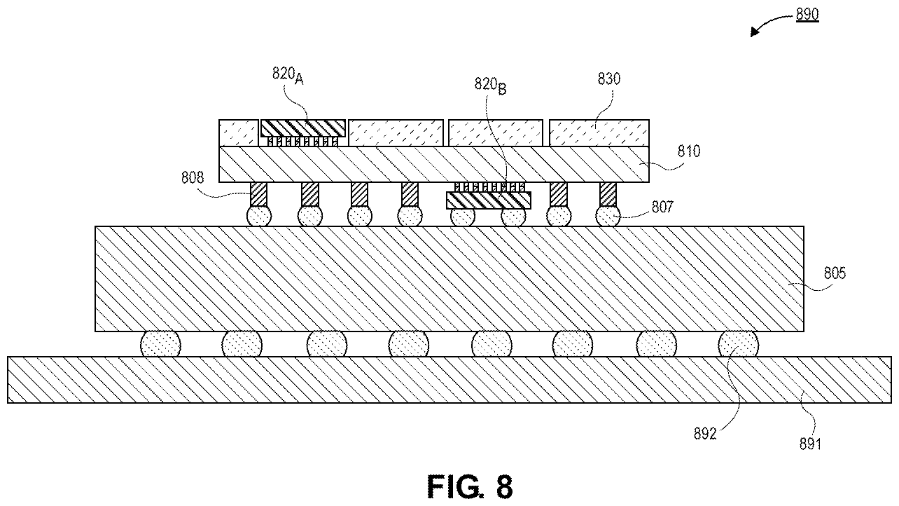

Referring now to FIG. 8, a cross-sectional illustration of an electronic system 890 is shown, in accordance with an embodiment. In an embodiment, the electronic package 890 comprises a board 891, such as a printed circuit board (PCB). A package substrate 805 is coupled to the board 891 by interconnects 892. While shown as solder balls, it is to be appreciated that any interconnect architecture (e.g., pins, wires, solder, etc.) may be used, in accordance with an embodiment.

In an embodiment, a die module is coupled to the package substrate 805. The die module may comprise a base die 810. The base die 810 may comprise a plurality of functional blocks (e.g., processor cores, memory blocks, IO lanes, etc.). In some embodiments, one or more of the functional blocks are defective. As such, replacement chiplets 820 are mounted to the base die 810. For example, the replacement chiplets 820 may be mounted to the top of the base die 810 (chiplet 820_{A}) or to the bottom of the base die 810 (chiplet 820_{B}). The replacement chiplets 820 may be mounted to the base die 810 with a high density interconnect architecture, such as hybrid bonding.

In an embodiment, the die module may further comprise dummy dies 830 that are over the top surface of the base die 810. The dummy dies 830 may be provided for thermal and mechanical reasons, such as described in greater detail above. In an embodiment, the base die 810 may be coupled to the package substrate 805 by pillars 808 and interconnects 807. The pillars 808 provide a standoff height to allow for the replacement chiplet 820_{B} to be provided below the base die 810.

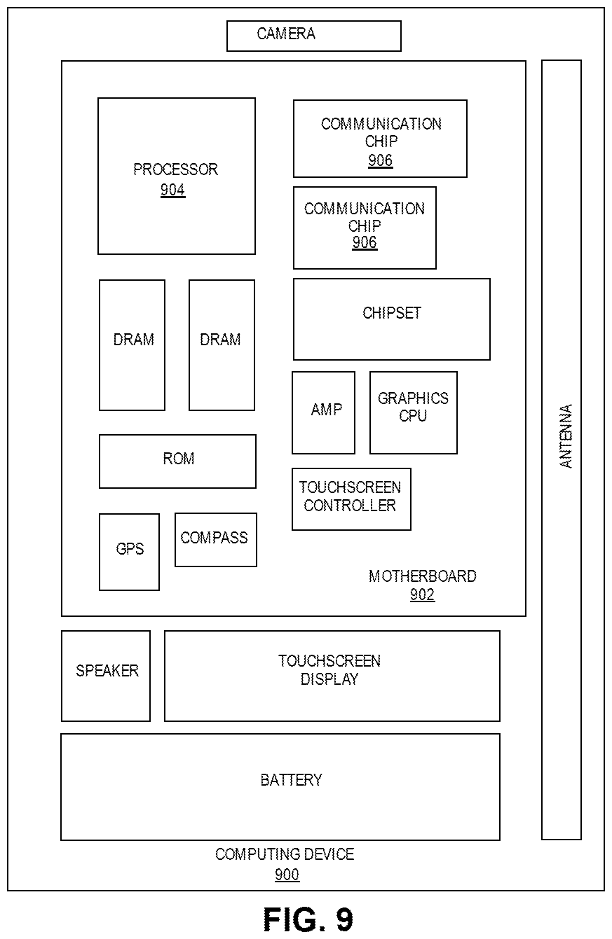

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package that comprises a die module with a base die and replacement chiplets coupled to the base die, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package that comprises a die module with a base die and replacement chiplets coupled to the base die, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a die module, comprising: a base die, wherein the base die comprises a functional block; and a chiplet coupled to the base die proximate to the functional block, wherein the chiplet comprises similar functionality as the functional block.

Example 2: the die module of Example 1, wherein the functional block is isolated from the circuitry of the base die, and the chiplet replaces the functional block.

Example 3: the die module of Example 1 or Example 2, wherein the functional block is a processor core.

Example 4: the die module of Example 1 or Example 2, wherein the functional block is an IO block.

Example 5: the die module of Example 1 or Example 2, wherein the functional block is a memory block.

Example 6: the die module of Examples 1-5, wherein the chiplet is coupled to the base die with a hybrid bonding architecture.

Example 7: the die module of Example 6, wherein interconnects in the hybrid bonding architecture have a pitch that is approximately 10 μm or smaller.

Example 8: the die module of Examples 1-7, wherein the base die has a backside surface and a front side surface, wherein first level interconnects (FLIs) are on the front side surface of the base die.

Example 9: the die module of Example 8, wherein the chiplet is coupled to the backside surface of the base die.

Example 10: the die module of Example 9, wherein the base die comprises through silicon vias to connect to the chiplet.

Example 11: the die module of Example 8, wherein the chiplet is coupled to the front side surface of the base die.

Example 12: the die module of Example 11, wherein the chiplet comprises through silicon vias to connect to the base die.

Example 13: the die module of Examples 1-12, further comprising: a dummy die adjacent to the chiplet, wherein the dummy die has a surface that is substantially coplanar with a surface of the chiplet facing away from the base die.

Example 14: the die module of Example 13, wherein the dummy die is coupled to the base die by hybrid bonding or an adhesive.

Example 15: an electronic package, comprising: a package substrate; and a die module coupled to the package substrate, wherein the die module comprises: a base die with a first surface and a second surface, wherein the first surface faces the package substrate, and wherein the base die comprises a plurality of functional blocks; and a chiplet coupled to the base die, wherein the chiplet replaces a functionality of one of the plurality of functional blocks.

Example 16: the electronic package of Example 15, wherein the functional block that is replaced is a processor core.

Example 17: the electronic package of Example 15, wherein the functional block that is replaced is an IO block.

Example 18: the electronic package of Examples 15-17, wherein the chiplet is over the first surface of the base die.

Example 19: the electronic package of Examples 15-17, wherein the chiplet is over the second surface of the base die.

Example 20: the electronic package of Examples 15-19, further comprising: a dummy die adjacent to the chiplet, wherein the dummy die is a silicon substrate without active circuitry.

Example 21: the electronic package of Examples 15-20, wherein the chiplet is coupled to the base die by hybrid bonding.

Example 22: the electronic package of Example 21, wherein interconnects of the hybrid bonding have a pitch that is approximately 10 μm or smaller.

Example 23: an electronic system, comprising: a board; a package substrate coupled to the board; and a die module coupled to the package substrate, wherein the die module comprises: a base die with a plurality of functional blocks, wherein individual ones of the plurality of functional blocks comprise selector circuitry; and a chiplet coupled to the base die over one of the plurality of functional blocks, wherein the chiplet is selected by the selector circuitry and the respective functional block is turned off

Example 24: the electronic system of Example 23, wherein the chiplet is a processor core.

Example 25: the electronic system of Example 23, wherein the chiplet is an IO block.

What is claimed is:

1. A die module, comprising:
a base die, wherein the base die comprises a functional block; and
a chiplet coupled to the base die proximate to the functional block, wherein the chiplet comprises similar functionality as the functional block.

2. The die module of claim 1, wherein the functional block is isolated from the circuitry of the base die, and the chiplet replaces the functional block.

3. The die module of claim 1, wherein the functional block is a processor core.

4. The die module of claim 1, wherein the functional block is an IO block.

5. The die module of claim 1, wherein the functional block is a memory block.

6. The die module of claim 1, wherein the chiplet is coupled to the base die with a hybrid bonding architecture.

7. The die module of claim 6, wherein interconnects in the hybrid bonding architecture have a pitch that is approximately 10 μm or smaller.

8. The die module of claim 1, wherein the base die has a backside surface and a front side surface, wherein first level interconnects (FLIs) are on the front side surface of the base die.

9. The die module of claim 8, wherein the chiplet is coupled to the backside surface of the base die.

10. The die module of claim 9, wherein the base die comprises through silicon vias to connect to the chiplet.

11. The die module of claim 8, wherein the chiplet is coupled to the front side surface of the base die.

12. The die module of claim 11, wherein the chiplet comprises through silicon vias to connect to the base die.

13. The die module of claim 1, further comprising:
a dummy die adjacent to the chiplet, wherein the dummy die has a surface that is substantially coplanar with a surface of the chiplet facing away from the base die.

14. The die module of claim 13, wherein the dummy die is coupled to the base die by hybrid bonding or an adhesive.

15. An electronic package, comprising:
a package substrate; and
a die module coupled to the package substrate, wherein the die module comprises:
a base die with a first surface and a second surface, wherein the first surface faces the package substrate, and wherein the base die comprises a plurality of functional blocks; and
a chiplet coupled to the base die, wherein the chiplet replaces a functionality of one of the plurality of functional blocks.

16. The electronic package of claim 15, wherein the functional block that is replaced is a processor core.

17. The electronic package of claim 15, wherein the functional block that is replaced is an IO block.

18. The electronic package of claim 15, wherein the chiplet is over the first surface of the base die.

19. The electronic package of claim 15, wherein the chiplet is over the second surface of the base die.

20. The electronic package of claim 15, further comprising:
a dummy die adjacent to the chiplet, wherein the dummy die is a silicon substrate without active circuitry.

21. The electronic package of claim 15, wherein the chiplet is coupled to the base die by hybrid bonding.

22. The electronic package of claim 21, wherein interconnects of the hybrid bonding have a pitch that is approximately 10 μm or smaller.

23. An electronic system, comprising:
a board;
a package substrate coupled to the board; and
a die module coupled to the package substrate, wherein the die module comprises:
a base die with a plurality of functional blocks, wherein individual ones of the plurality of functional blocks comprise selector circuitry; and
a chiplet coupled to the base die over one of the plurality of functional blocks, wherein the chiplet is selected by the selector circuitry and the respective functional block is turned off.

24. The electronic system of claim 23, wherein the chiplet is a processor core.

25. The electronic system of claim 23, wherein the chiplet is an IO block.
